(19) United States
(12) Patent Application Publication
(10) Pub. No.: US 2006/0254715 A1
(43) Pub. Date: Nov. 16, 2006

(54) METHOD AND APPARATUS FOR VERTICAL TRANSFER OF SEMICONDUCTOR SUBSTRATES IN A CLEANING MODULE

(76) Inventors: Joseph Yudoovsky, Campbell, CA (US); Hui Chen, Burlingame, CA (US)

Correspondence Address: PATTERSON & SHERIDAN, LLP, 3040 POST OAK BOULEVARD, SUITE 1500, HOUSTON, TX, 77056, US

(21) Appl. No.: 11/382,828

(22) Filed: May 11, 2006

Related U.S. Application Data
(60) Provisional application No. 60/680,857, filed on May 12, 2005.

(51) Int. Cl. H01L 21/306

(52) U.S. Cl. 156/345.32

(57) ABSTRACT

A substrate handler is provided. In one embodiment, the substrate handler includes a first and second carriage coupled to a rail. A first robot having at least two grippers is attached to the first carrier. A second robot having at least one gripper is coupled to the second carriage. The first carriage is independently positionable along the rail relative to the second carriage. As each carriage has a separate actuator, the movements of the first and second robot are decoupled, thereby allowing increased throughput. The substrate handler is particularly suitable for using in a planarization system having an integrated substrate cleaner.

### CROSS-REFERENCE TO RELATED APPLICATIONS

This application claims benefit of U.S. provisional patent application Ser. No. 60/680,857, filed May 12, 2005, which is herein incorporated by reference.

### BACKGROUND OF THE INVENTION

1. Field of the Invention

Embodiments of the present invention generally relate to a method and apparatus for handling semiconductor substrates.

2. Description of Related Art

In the process of fabricating modern semiconductor integrated circuits (ICs), it is necessary to develop various material layers over previously formed layers and structures. However, the prior formations often leave the top surface topography unsuitable for the position of subsequent layers of material. For example, when printing a photolithographic pattern having small geometries over previously formed layers, a shallow depth of focus is required. Accordingly, it becomes essential to have a flat and planar surface, otherwise, some of the pattern will be in focus while other parts of the pattern will not. In addition, if the irregularities are not leveled prior to certain processing steps, the surface topography of the substrate can become even more irregular, causing further problems as the layers stack up during further processing. Depending on the die type and the size of geometries involved, the surface irregularities can lead to poor yield and device performance. Consequently, it is desirable to achieve some type of planarization, or polishing, of films during IC fabrication.

One method for planarizing a layer during IC fabrication is chemical mechanical polishing (CMP). In general, CMP involves the relative movement of the substrate against a polishing material to remove surface irregularities from the substrate. The polishing material is wetted with a polishing fluid that typically contains at least one of an abrasive or chemical polishing composition. This process may be electrically assisted to electrochemically planarize conductive material on the substrate.

Once polished, the semiconductor substrate is transferred to a series of cleaning modules that remove the abrasive particles and/or other contaminants that cling to the substrate after polishing. The cleaning modules must remove any remaining polishing materials before they can harden on the substrate and create defects. These cleaning modules may include, for example, a megasonic cleaner, a scrubber or scrubbers, and a dryer. The cleaning modules that support the substrates in a vertical orientation are especially advantageous, as they also utilize gravity to enhance removal of particles during the cleaning process, and are also typically more compact.

Although present CMP processes have been shown to be robust and reliable systems, the configuration of the system equipment requires the substrates to be cleaned in a generally linear processing sequence. As a single substrate handler is typically utilized to move substrates through the cleaner, the substrate transfer speed through the cleaner is limited. Moreover, in configurations using a single substrate handler, cross-talk of chemicals between cleaning modules and/or the dryer diminishes the effectiveness of the cleaning process.

Therefore, there is a need in the art for a versatile substrate handler for use in an automated cleaning system.

### SUMMARY OF THE INVENTION

A substrate handler is provided. In one embodiment, the substrate handler includes a first and second carriage positionable along a guide. A first robot having two grippers is attached to the first carrier. A second robot having at least one gripper is coupled to the second carriage. The first carriage is independently positionable along the guide relative to the second carriage. As each carriage has a separate actuator, the movements of the first and second robot are decoupled, thereby allowing increased throughput. The substrate handler is particularly suitable for use in a planarization system having an integrated substrate cleaner.

In another embodiment, another substrate handler is provided. The substrate handler comprising a rail, a first carriage and a second carriage coupled to the rail, a first robot coupled to the first carriage and having at least two grippers, and a second robot coupled to the second carriage and having at least one gripper, wherein the first carriage is independently positionable along the rail relative to the second carriage.

In another embodiment, a substrate cleaning system is provided. The subtrate cleaning system comprising a plurality of cleaning modules, a first vertically positionable robot disposed above the plurality of cleaning modules, and a second vertically positionable robot disposed above the plurality of cleaning modules, wherein the first and second robots are selectively positionable over each of the plurality of cleaning modules, and wherein the first and second robots move vertically to interface with each of the plurality of cleaning modules independent of the each other.

In another embodiment, a method for cleaning a substrate is provided. The method comprising positioning a first and a second robot along a first axis of motion over a plurality of cleaning modules, retrieving a substrate from an input module and placing the substrate in a first cleaning module by the first robot, retrieving the substrate from the first cleaning module and placing the substrate in the second cleaning module by the first robot, retrieving the substrate from the second cleaning module and placing the substrate in a third cleaning module by the first robot, retrieving the substrate from the third cleaning module and placing the substrate in a dryer by the second robot, and retrieving the substrate from the dryer and placing the substrate in an output module by the second robot.

In another embodiment, a method is provided that includes utilizing at least two robots to move substrates through a cleaner of a polishing system, wherein one robot performs all substrate transfers to a drying module of the cleaner.

### BRIEF DESCRIPTION OF THE DRAWINGS

So that the manner in which the above recited embodiments of the invention are obtained and can be understood in detail, a more particular description of the invention, briefly summarized above, may be had by reference to the embodiments thereof, which are illustrated in the appended drawings. It is to be noted, however, that the appended drawings illustrate only typical embodiments of the invention, and are therefore not to be considered limiting of its scope, for the invention may admit to other equally effective embodiments.

FIG. 1 illustrates a top view of a semiconductor substrate polishing and cleaning system;

FIG. 2 depicts a front view of one embodiment of a substrate handler;

FIG. 3 is a top view of the substrate handler of FIG. 2;

FIG. 4 is a side view of one embodiment of a gripper; and

FIGS. 5A-I are schematic diagrams of the substrate handler in one mode of operation.

To facilitate understanding, identical reference numerals have been used, wherever possible, to designate identical elements that are common to the Figures. Additionally, elements of one embodiment may be advantageously adapted for utilization in other embodiments described herein.

### DETAILED DESCRIPTION

Embodiments for an apparatus and method for transferring substrates through a cleaning module of a chemical mechanical planarizing (CMP) system are provided. Although the system is illustratively described having at least two processing stations suitable for planarizing a substrate disposed around a central substrate transfer device, it is contemplated that the system may be arranged in other configurations. Furthermore, although the embodiments disclosed below focus primarily on removing material from, e.g., planarizing or polishing, a substrate, it is contemplated that the teachings disclosed herein may be used in other processing systems, for example, electroplating systems, where efficient transfer of substrates through an integrated cleaning module is desired.

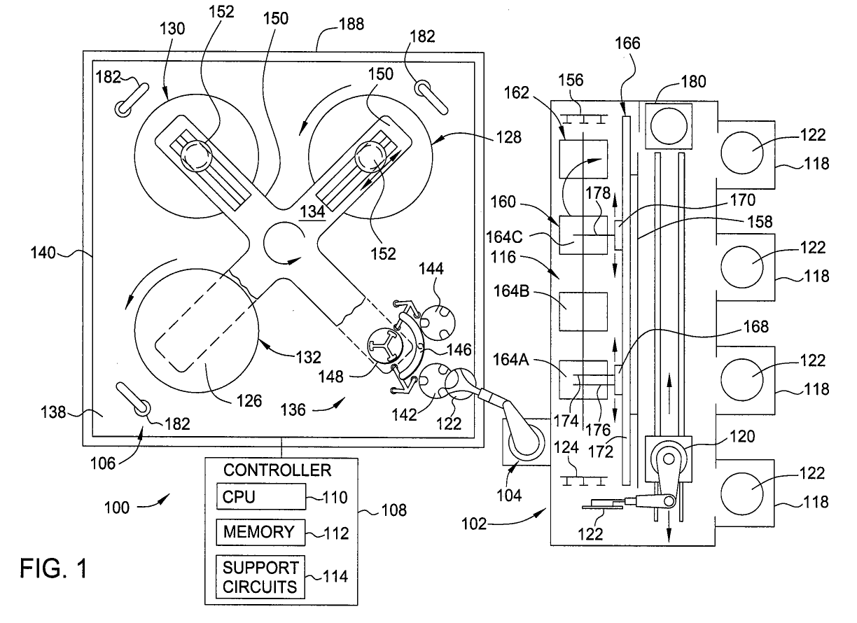

FIG. 1 is a plan view of one embodiment of a planarization system 100 having an apparatus for electrochemically processing a substrate. The exemplary system 100 generally comprises a factory interface 102, a loading robot 104, and a planarizing module 106. The loading robot 104 is disposed proximate the factory interface 102 and the planarizing module 106 to facilitate the transfer of substrates 122 therebetween.

A controller 108 is provided to facilitate control and integration of the modules of the system 100. The controller 108 comprises a central processing unit (CPU) 110, a memory 112 and support circuits 114. The controller 108 is coupled to the various components of the system 100 to facilitate control of, for example, the planarizing, cleaning and transfer processes.

The factory interface 102 generally includes a cleaner 116 and one or more wafer cassettes 118. An interface robot 120 is employed to transfer substrates 122 between the wafer cassettes 118, the cleaner 116 and an input module 124. The input module 124 is positioned to facilitate transfer of substrates 122 between the planarizing module 106 and the factory interface 102 by grippers, for example, vacuum grippers or mechanical clamps.

The planarizing module 106 includes at least one chemical mechanical planarizing (CMP) or electrochemical mechanical planarizing station. In one embodiment, the planarizing module 106 includes at least one bulk electrochemical mechanical planarizing (ECMP) station 128, and optionally, at least one conventional chemical mechanical planarizing (CMP) station 132 disposed in an environmentally controlled enclosure 188. Examples of planarizing modules 106 that can be adapted to benefit from the invention include MIRRA®, MIRRA MESA™, REFLEXION® , REFLEXION® LK, and REFLEXION LK EcmP™ Chemical Mechanical Planarizing Systems, all available from Applied Materials, Inc. of Santa Clara, Calif. Other planarizing modules, including those that use processing pads, planarizing webs, or a combination thereof, and those that move a substrate relative to a planarizing surface in a rotational, linear or other planar motion may also be adapted to benefit from the invention.

In the embodiment depicted in FIG. 1, the planarizing module 106 includes one bulk ECMP station 128, a second ECMP station 130 and one CMP station 132. Bulk removal of conductive material from the substrate is performed through an electrochemical dissolution process at the bulk ECMP station 128. After the bulk material removal at the bulk ECMP station 128, residual conductive material is removed from the substrate at the residual ECMP station 130 through a second electrochemical mechanical process. It is contemplated that more than one residual ECMP station 130 may be utilized in the planarizing module 106.

A conventional chemical mechanical planarizing process is performed at the planarizing station 132 after processing at the residual ECMP station 130. An example of a conventional CMP process for the removal of copper is described in U.S. Pat. No. 6,451,697, issued Sep. 17, 2002, which is incorporated by reference in its entirety. An example of a conventional CMP process for the barrier removal is described in U.S. patent application Ser. No. 10/187,857, filed Jun. 27, 2002, which is incorporated by reference in its entirety. It is contemplated that other CMP processes may be alternatively performed. As the CMP stations are conventional in nature, further description thereof has been omitted for the sake of brevity.

The exemplary planarizing module 106 also includes a transfer station 136 and a carousel 134 that are disposed on an upper or first side 138 of a machine base 140. In one embodiment, the transfer station 136 includes an input buffer station 144, an output buffer station 142, a transfer robot 146 and a load cup assembly 148. The input buffer station 144 receives substrates from the factory interface 102 by the loading robot 104. The loading robot 104 is also utilized to return polished substrates from the output buffer station 142 to the factory interface 102. The transfer robot 146 is utilized to move substrates between the buffer stations 144,142 and the load cup assembly 148.

In one embodiment, the transfer robot 146 includes two gripper assemblies, each having pneumatic gripper fingers that hold the substrate by the substrate's edge. The transfer robot 146 may simultaneously transfer a substrate to be processed from the input buffer station 144 to the load cup assembly 148 while transferring a processed substrate from the load cup assembly 148 to the output buffer station 142. An example of a transfer station that may be used to advantage is described in U.S. patent application Ser. No. 6,156,124, issued Dec. 5, 2000 to Tobin, which is herein incorporated by reference in its entirety.

The carousel 134 is centrally disposed on the base 140. The carousel 134 typically includes a plurality of arms 150, each supporting a planarizing head assembly 152. Two of the arms 150 depicted in FIG. 1 are shown in phantom such that a planarizing surface 126 of the bulk ECMP station 128 and the transfer station 136 may be seen. The carousel 134 is indexable such that the planarizing head assemblies 152 may be moved between the planarizing stations 128, 132 and the transfer station 136. One carousel that may be utilized to advantage is described in U.S. Pat. No. 5,804,507, issued Sep. 8, 1998 to Perlov, et al., which is hereby incorporated by reference in its entirety.

A conditioning device 182 is disposed on the base 140 adjacent each of the planarizing stations 128, 132. The conditioning device 182 periodically conditions the planarizing material disposed in the stations 128, 132 to maintain uniform planarizing results.

Optionally, substrates exiting the cleaner 116 may be tested in a metrology system 180 disposed in the factory interface 102. The metrology system 180 may include an optical measuring device, such as the NovaScan 420, available from Nova Measuring Instruments, Inc. located in Sunnyvale, Calif. The metrology system 180 may include a buffer station (not shown) for facilitating entry and egress of substrates from the optical measuring device or other metrology device. One such suitable buffer is described in U.S. Pat. No. 6,244,931, issued Jun. 12, 2001 to Pinson, et al., which is hereby incorporated by reference in its entirety.

The cleaner 116 removes polishing debris and/or polishing fluid from the polished substrates that remains after polishing. Substrates are generally moved through the plurality of cleaning modules 160 by the substrate handler 166 during cleaning. One cleaner that may be adapted to benefit from the present invention is described in U.S. patent application Ser. No. 10/286,404, filed Nov. 1, 2002, which is herein incorporated by reference in its entirety. In one embodiment, the cleaner 116 includes a plurality of single substrate cleaning modules 160, as well as the input module 124, a dryer 162, and a substrate handler 166 disposed above the plurality of cleaning modules 160. The input module 124 serves as a transfer station between the factory interface 102, the cleaner 116 and the planarizing module 106. The dryer 162 dries substrates exiting the cleaner 116 and facilitates substrate transfer between the cleaner 116 and the factory interface 102. The dryer 162 may be a spin-rinse-dryer. In another example, a suitable dryer 162 may be found as part of the MESA™ and Desica® Substrate Cleaner, both available from Applied Materials, Inc., of Santa Clara, Calif.

In the embodiment depicted in FIG. 1, the cleaner 116 includes three cleaning modules 160, shown as a megasonic clearing module 164A, a first brush module 164B and a second brush module 164C. However, it is to be appreciated that the invention may be used with cleaning systems incorporating any number of modules. Each of the modules 164A-C is configured to process a vertically oriented substrate, i.e., one in which the polished surface is in a substantially vertical plane.

In operation, the system 100 is initiated with a substrate 122 being transferred from one of the cassettes 118 to the input module 124 by the interface robot 120. The robot 104 then removes the substrate from the input module 124 and transfers it to the planarizing module 106, where the substrate is polished while in a horizontal orientation. Once the substrate is polished, the robot 104 extracts the substrate 122 from the planarizing module 106 and places it in the input module 124 in a vertical orientation. The substrate handler 166 retrieves the substrate from the input module 124 and indexes the substrate through at least one of the cleaning modules 160 of the cleaner 116. Each of the modules 160 is adapted to support a substrate in a vertical orientation throughout the cleaning process. Once cleaned, the substrate handler 166 transfers the substrate to the output module 156, where it is flipped to a horizontal orientation and returned by the interface robot 120 to one of the cassettes 118. In another embodiment, the dryer 162 may facilitate substrate transfer by tilting the substrate to a horizontal position and moving it upward for transfer to a cassette 118 by the interface robot 120. Optionally, the interface robot 120 or substrate handler 166 may transfer the substrates to the metrology system 180 prior to the substrate's return to the cassette 118.

The substrate handler 166 generally includes a first robot 168 and a second robot 170. The first robot 168 includes at least one gripper (two grippers 174, 176 are shown) and is configured to transfer the substrate between at least the input module 124 and the cleaning modules 160. The second robot 170 includes at least one gripper (a gripper 178 is shown) and is configured to transfer the substrate between at least one of the cleaning modules 160 and the dryer 162. Optionally, the second robot 170 may be configured to transfer the substrate between the dryer 162 and the metrology system 180.

In the embodiment depicted in FIG. 1, the substrate handler 166 includes a rail 172 coupled to a partition 158 separating the cassettes 118 and interface robot 120 from the cleaner 116. The robots 168,170 are configured to move laterally along the rail 172 to facilitate access to the cleaning modules 160, dryer 162 and input module 124.

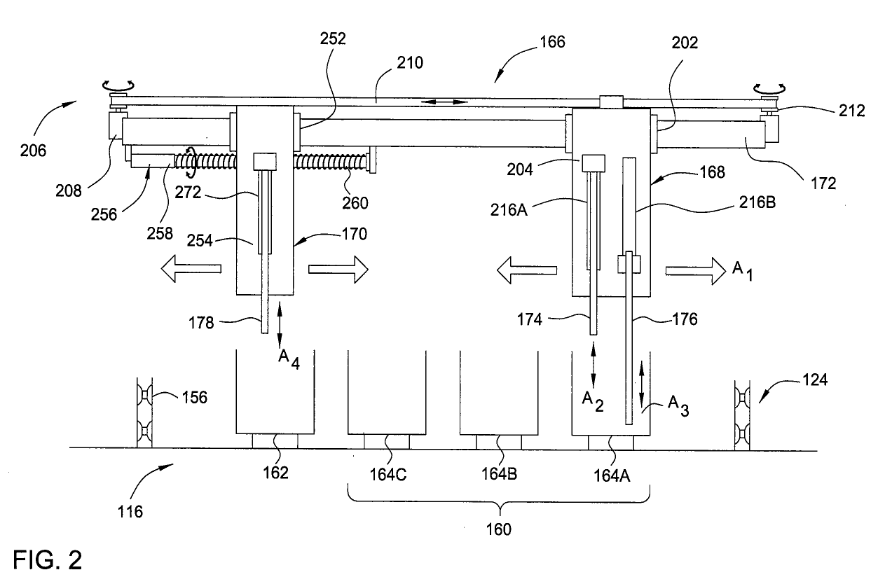

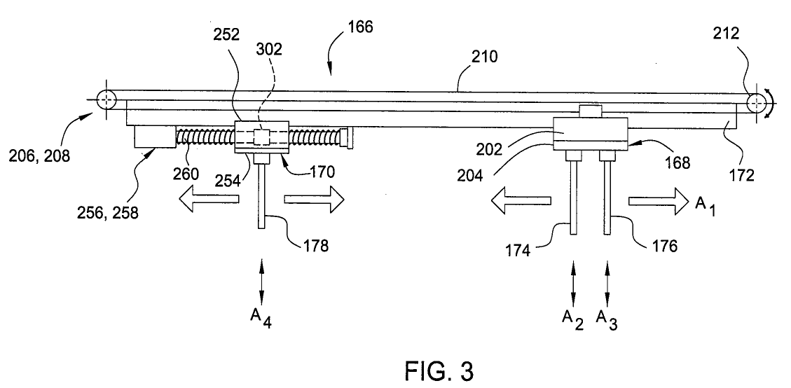

FIGS. 2-3 depict front and top views of the substrate handler 166 according to one embodiment of the invention. The first robot 168 of the substrate handler 166 includes a carriage 202, a mounting plate 204 and the substrate grippers 174, 176. The carriage 202 is slidably mounted on the rail 172 and is driven horizontally by an actuator 206 along a first axis of motion A₁ defined by the rail 172. The actuator 206 includes a motor 208 coupled to a belt 210. The carriage 202 is attached to the belt 210. As the motor 208 advances the belt 210 around the sheave 212 positioned at one end of the cleaner 116, the carriage 202 moves along the rail 172 to selectively position the first robot 168. The motor 208 may include an encoder (not shown) to assist in accurately positioning the first robot 168 over the input module 124 and the various cleaning modules 160. Alternatively, the actuator 206 may be any form of a rotary or linear actuator capable of controlling the position of the carriage 202 along the rail 172. In one embodiment, the carriage 202 is driven by a linear actuator having a belt drive, such as the GL15B linear actuator commercially available from THK Co., Ltd. located in Tokyo, Japan. In one embodiment, the belt 210 may be enclosed by a cover, for example a shell, used to keep the belt clean from debris and other materials that may be in the proximity of the substrate handler 166, which can come in contact with the belt 210. In one embodiment, the belt 210 may be enclosed within the rail in order to keep it clean from debris and other material.

The mounting plate 204 is coupled to the carriage 202. The mounting plate 204 includes at least two parallel tracks 216A-B along which the positions of the grippers 174, 176 are independently actuated along a second and third axes of motion A₂, A₃. The second and third axes of motion A₂, A₃ are oriented perpendicular to the first axis A₁.

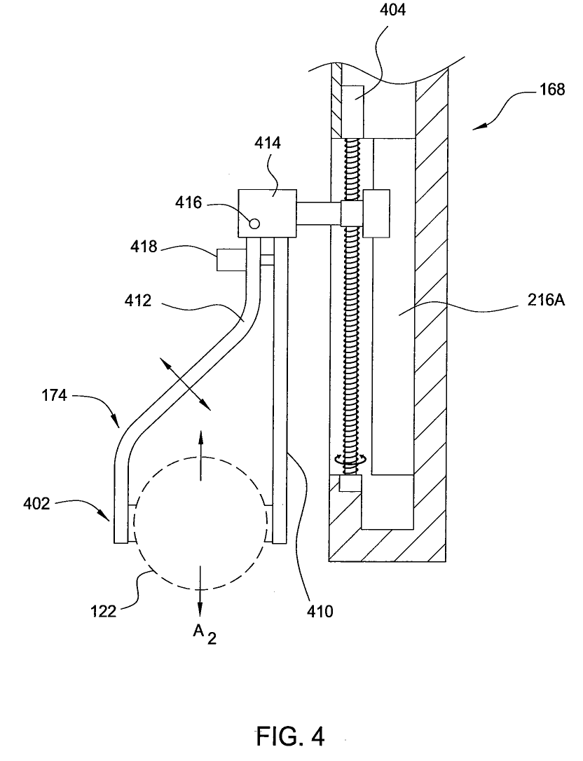

FIG. 4 is a side view of one embodiment of the second gripper 176. The grippers 174, 178 are similarly configured. The second gripper 176 includes a substrate gripping device 402 and an actuator 404. The actuator 404 may be a lead screw, cylinder or other mechanic suitable for positioning the vertical position of the gripping device 402 along the track 216A in the direction defined by the second axis of motion A₂. In one embodiment, the actuator 404 is a lead screw slide assembly, also available from THK Co., Ltd.

The gripping device 402 includes a first arm 410 and a second arm 412 configured to grip the outer edges of a vertically oriented substrate (as shown in FIG. 4). Alternatively, the gripping device 402 may be a robotic end effector having an electrostatic chuck, vacuum chuck, edge clamp or other substrate gripping device. In the embodiment depicted in FIG. 4, the first arm 410 extends from a bracket 414, while the second arm 412 rotates about a pin 416 extending through the bracket 414. A gripper actuator 418 is coupled to the second arm 412 to control the rotation of the arm 412 about the pin 416 to selectively grip and release a substrate 122 (shown in phantom) between the distal ends of the arms 410, 412 along axis A₅.

The second robot 170 of the substrate handler 166 includes a carriage 252, a mounting plate 254 and the gripper 178. The carriage 252 is mounted on the rail 172 and is driven horizontally by an actuator 256 along the first axis of motion A₁ defined by the rail 172. In the embodiment depicted in FIGS. 1-3, the actuator 256 includes a motor 258 and lead screw 260. A nut 302 (shown in phantom in FIG. 3), attached to the carriage 202, is advanced along the lead screw 260, as the motor 258 turns, thereby moving the carriage 252 along the rail 172 to selectively position the second robot 170. The motor 258 may include an encoder to assist in accurately positioning the second robot 170 over the output module 156, the dryer 162 and at least one of the cleaning modules 160. In the embodiment depicted in FIGS. 1-3, the second robot 170 is configured to perform all substrate transfers between the second brush module 164C and the dryer 162. This convention advantageously minimizes the exposure of the dryer 162 to chemicals and other matter disposed in the first cleaning modules 164A, 164B that remove the bulk of contaminants from the polished substrate. Alternatively, the actuator 256 may be any form of a linear or rotary actuator suitable for controlling the position of the carriage 252 along the rail 172.

The mounting plate 254 is coupled to the carriage 252. The mounting plate 254 includes a track 272 along which the position of the gripper 178 is controlled along a fourth axis of motion A₄. The fourth axis of motion A₄ is parallel to the second and third axes of motion A₂, A₃, and is oriented perpendicular to the first axis A₁. The gripper 178 is vertically actuated and grips a substrate as described with reference to the gripper 176 discussed with reference to FIG. 4 above. As such, the vertical position of the grippers 174, 176, and 178 and gripping action may be controlled independent from each other.

Referring to FIGS. 2-3, the first and second robots 168, 170 of the substrate handler 166 are capable of at least three axes of motion with respect to the cleaner 116: one horizontal (x axis—along the rail 172, see first axis A₁) and at least three vertical (y axis—one each for the three independently controllable gripping devices 174, 176, 178, see second, third and fourth axes A₂, A₃, A₄). In addition, each gripping device has an additional axis (as is shown for one gripper in FIG. 4) of motion along the plane in which it grips the substrate (z axis—i.e., coplanar with the plane area of the substrate), which is perpendicular to the axes A₁-A₄.

One benefit of the substrate handler 166 of the present invention is that the gripping devices of each gripper 174, 176, 178 are capable of moving independently of one another, thus allowing process sequences (i.e., the order that substrates pass through the modules 160) within the cleaner to be varied. Furthermore, two gripping devices 206 on one arm 204 may effectuate a substrate swap in one cleaning module, without affecting the processes or operation in other modules.

Additionally, as the second robot 170 utilizes the same rail 174 as the first robot, the cost of the substrate handler 166 is reduced compared to transfer devices having comparable capabilities. Moreover, as the required mass and range of motion of the second robot 170 is less than the first robot 168, precision ball screw actuators are suitable for motion control of the second robot 170. Advantageously, ball screw actuators have repeatable, high precision motion and generate less particulate as compared to belt drive systems. Furthermore, as the motion of the first and second robots 168, 170 are decoupled (i.e., able to independently perform substrate transfer tasks), the substrate transfer requirements of the first robot 168 is reduced by 25 percent as compared to substrate handlers having a single robot, thereby allowing a significant increase in substrate throughput. In yet another benefit of the invention, the dedicated transfer of substrates between the second brush module 164C and the dryer 162 reduces cross contamination, particularly as the megasonic and first brush modules 164A, 164B have high chemical concentrations, thereby reducing the possibility of substrate contamination during drying.

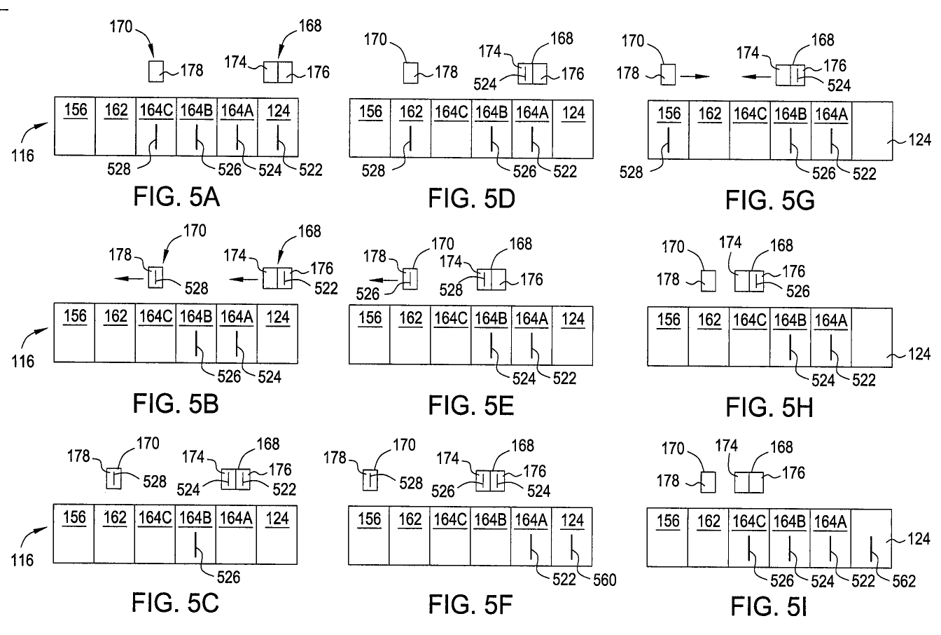

One mode of operation of the substrate handler 166 is illustrated in the schematics depicted in FIGS. 5A-I. Although the cleaner 116 is schematically shown in FIGS. 5A-I having three adjoining cleaning modules 164A-C, it is contemplated that the cleaner 116 may include any number of cleaning modules 160.

FIG. 5A depicts the cleaner 116 during normal processing of substrates returning from the polishing module 106. In the embodiment depicted in FIG. 5A, processed 522, 524, 526, 528 substrates are respectively shown positioned in the input module 124, the megasonic module 164A, and the first and second brush modules 164B-C. The first robot 168 is positioned over the input module 124, while the second robot 170 is positioned over the second brush module 164C.

As shown in FIG. 5B, the second gripper 162 of the first robot 168 retrieves the substrate 522. The second robot 170 retrieves the substrate 528 from the second brush module 164C. The first robot 168 moves laterally to a position over the megasonic module 164A, while the second robot 170 moves laterally to a position over the dryer 162.

As shown in FIG. 5C, the first gripper 174 retrieves the substrate 524 residing in the megasonic module 164A. Once the substrate 524 is removed from the megasonic module 164A, the second gripper 176 extends to place the substrate 522 retrieved from the input module 124 into the megasonic module 164A. In the meantime, the second robot 170 extends its gripper 178 to place the substrate 528 retrieved from the second brush module 164C into the dryer 162, as shown in FIG. 5D.

As shown in FIG. 5E-G, the dried substrate 528 is retrieved from the dryer 162 by the first gripper 178 of the second robot 170, and moved laterally to a position over the output module 156. The gripper 178 of the second robot 170 then extends to place the substrate in the output module 156 where it can be accessed by the interface robot 120.

Also shown in FIGS. 5E-G, the first robot 168 moves laterally to position the substrate 524 over the first brush module 164B. The second gripper 176 extends to retrieve the substrate 526 disposed in the first brush module 164B. The first gripper 174 of the first robot 168 then extends to place the substrate 524 retrieved from the megasonic module 164A into the first brush module 164B.

Referring to FIGS. 5E-G and FIG. 1, an unprocessed substrate 560 is transferred to the input module 124 by the interface robot 120 while the processed substrates 522, 524, 526, 528 are advanced through the cleaner 116. The wet robot 104 then retrieves the substrate 560 from the input module 124 and transfers the substrate 500 to the planarizing module 106 for processing. Although this sequence of loading the planarizing module 106 is shown in FIGS. 5E-G, the unprocessed substrates may be transferred from the cassettes 118 to the planarizing module 106 during other periods of operation.

Returning to FIGS. 5H-I, the first robot 168 moves the substrate 526 retrieved from the first brush module 164B to a position over the second brush module 164C. The second gripper 176 is extended to place the substrate 526 in the second brush module 164C. In the interim, a substrate 562 returning from the planarizing module 106 after processing is disposed in the input module 124, returning the cleaner 116 to the condition shown in FIG. 5I. The above reference steps may then be repeated to continue transporting the substrates through the individual modules 160 of the cleaner 116.

Thus, the present invention represents a significant advancement in the field of semiconductor substrate cleaning and polishing. The substrate handler is adapted to support and transfer vertically oriented substrates, allowing it to be used in conjunction with cleaning systems that use minimal space. Furthermore, the handler is capable of multiple axes of vertical motion, making it more versatile and more easily adaptable to various substrate processing sequences.

While the foregoing is directed to embodiments of the present invention, other and further embodiments of the invention may be devised without departing from the basic scope thereof, and the scope thereof is determined by the claims that follow.

1. A substrate handler, comprising:
a rail;
a first carriage and a second carriage coupled to the rail;
a first robot coupled to the first carriage and having at least two grippers; and
a second robot coupled to the second carriage and having at least one gripper, wherein the first carriage is independently positionable along the rail relative to the second carriage.

2. The substrate handler of claim 1, wherein the at least two grippers of the first robot are configured to transfer a substrate between at least an input module and a first cleaning module or between at least a first cleaning module and a second cleaning module.

3. The substrate handler of claim 1, wherein the at least one gripper of the second robot is configured to transfer a substrate between at least one cleaning module and a dryer.

4. The substrate handler of claim 1, wherein the first and the second robots are configured to move laterally along the rail to facilitate access to a plurality of modules.

5. The substrate handler of claim 4, wherein the at least one of the modules is a cleaning module.

6. The substrate handler of claim 4, wherein the carriage is slidably mounted on the rail and is driven horizontally by an actuator along a first axis of motion defined by the rail.

7. The substrate handler of claim 6, wherein the actuator includes a motor coupled to a belt to advance the carriage along the first axis of motion to position the first robot.

8. The substrate handler of claim 7, wherein the belt is enclosed by a cover.

9. The substrate handler of claim 7, wherein the at least two grippers of the first robot are independently actuated along a second and a third axis of motion.

10. The substrate handler of claim 9, wherein the second and the third axis of motion are oriented perpendicular to the first axis.

11. The substrate handler of claim 1, wherein the first and the second robots are adapted to move horizontally by the actuator along the first axis of motion.

12. A substrate cleaning system comprising:
a plurality of cleaning modules;
a first vertically positionable robot disposed above the plurality of cleaning modules; and
a second vertically positionable robot disposed above the plurality of cleaning modules, wherein the first and second robots are selectively positionable over each of the plurality of cleaning modules, and wherein the first and second robots move vertically to interface with each of the plurality of cleaning modules independent of each other.

13. The substrate cleaning system of claim 12, wherein the first robot further comprises at least two grippers and the second robot further comprise at least one gripper.

14. The substrate cleaning system of claim 12, further comprising:
a plurality of laterally positionable carriage assemblies having the first and the second robot coupled thereto, and a motor for positioning the carriage assemblies.

15. The substrate handler of claim 12, wherein the at least two grippers of the first robot are configured to transfer a substrate from at least an input module and a first cleaning module, or transfer a substrate from the first cleaning module to a second cleaning module.

16. The substrate handler of claim 13, wherein the at least one gripper of the second robot is configured to transfer a substrate from at least one cleaning module to a dryer or transfer the substrate from the dryer to an output module.

17. The substrate handler of claim 16, wherein the dryer is adapted to facilitate substrate transfer by tilting the substrate to a horizontal position and then moving it upward for transfer to a cassette by an interface robot.

18. The substrate handler of claim 12, wherein the first and the second robots are configured to move laterally along the rail to facilitate access to a plurality of modules.

19. The substrate handler of claim 12, wherein the at least one of the modules is a cleaning module.

20. A method for cleaning a substrate comprising:
positioning a first and a second robot along a first axis of motion over a plurality of cleaning modules;
retrieving a substrate from an input module and placing the substrate in a first cleaning module by the first robot;
retrieving the substrate from the first cleaning module and placing the substrate in the second cleaning module by the first robot;
retrieving the substrate from the second cleaning module and placing the substrate in a third cleaning module by the first robot;
retrieving the substrate from the third cleaning module and placing the substrate in a dryer by the second robot; and
retrieving the substrate from the dryer and placing the substrate in an output module by the second robot.

21. The substrate handler of claim 20, wherein the first robot further comprises at least two grippers configured to transfer a substrate between at least an input module and a first cleaning module.

22. The substrate handler of claim 20, wherein the second robot further comprises at least one gripper configured to transfer a substrate between at least a second cleaning module and a dryer.

23. A method for cleaning a substrate comprising:
utilizing at least a first and a second robot to move substrates through a cleaner of a polishing system, wherein the second robot is adapted to perform all substrate transfers to a drying module of the cleaner.
